(19) United States
(12) Patent Application Publication
(10) Pub. No.: US 2016/0141276 A1
(43) Pub. Date: May 19, 2016

(54) LIGHT-EMITTING STRUCTURE FOR PROVIDING PREDETERMINED WHITENESS

(71) Applicants: LITE-ON OPTO TECHNOLOGY (CHANGZHOU) CO., LTD., CHANGZHOU CITY (CN); LITE-ON TECHNOLOGY CORPORATION, TAIPEI CITY (TW)

(72) Inventors: KUO-MING CHIU, NEW TAIPEI CITY (TW); Han-Hsing Peng, New Taipei City (TW)

(21) Appl. No.: 14/717,961

(22) Filed: May 20, 2015

Related U.S. Application Data
(63) Continuation-in-part of application No. 14/541,327, filed on Nov. 14, 2014.

(51) Int. Cl. H01L 25/075; H01L 33/50; H01L 33/62; H01L 33/64

(52) U.S. Cl. CPC H01L 25/0753; H01L 33/642; H01L 33/501; H01L 33/62

(57) ABSTRACT

A light-emitting structure for providing a predetermined whiteness includes a substrate and a light-emitting unit. The light-emitting unit includes a plurality of first and second light-emitting groups disposed on the substrate. Each first light-emitting group includes a plurality of first LED chips having a first predetermined wavelength. Each second light-emitting group includes a plurality of second LED chips having a second predetermined wavelength. When surface areas of the first and the second LED chips are substantially the same or currents passing through the first and the second LED chips are substantially the same in advance, the light-emitting structure can provide a predetermined whiteness according to different requirements by adjusting the current ratio or the surface area ratio of the first and the second LED chips, respectively.

### BACKGROUND OF THE INVENTION

1. Field of the Invention

The present disclosure relates to a light-emitting structure; in particular, to a light-emitting structure for increasing a light mixing effect among a plurality of LEDs of different wavelengths.

2. Description of Related Art

Typically, when a surface of an object reflects 80% of all light with wavelengths in the visible range, said surface is considered to be white. However, currently many white clothes are treated by bleaches and fluorescent whitening, producing a very white and very bright visual effect after carrying out an effective light energy transformation for light of short wavelength. So a light source which can provide a predetermined or adjustable super white light is in high demand in the market.

### SUMMARY OF THE INVENTION

The object of the present disclosure is to provide a light-emitting structure which has a plurality of first light-emitting groups and a plurality of second light-emitting groups are alternately and respectively disposed on the corresponding conductive tracks. Predetermined configuration of the ratio of emitting areas or adjustment of the ratio of currents of first and second light-emitting groups, the light-emitting structure of the present disclosure can provide whiteness according to need and improve light mixing effect. The present disclosure can improve light mixing effect. Additionally, through configuration of the ratio of areas or adjustment of the ratio of currents, the light-emitting structure of the present disclosure can provide whiteness according to need.

In order to further the understanding regarding the present disclosure, the following embodiments are provided along with illustrations to facilitate the disclosure of the present disclosure.

### BRIEF DESCRIPTION OF THE DRAWINGS

FIG. 1 shows a top view of a light-emitting structure according to the present disclosure wherein positive and negative solder pads of LED chips are arranged according to a first design;

FIG. 2 shows a top view of a light-emitting structure according to the present disclosure wherein positive and negative solder pads of LED chips are arranged according to a second design;

FIG. 3 shows a top view of a light-emitting structure according to the present disclosure wherein positive and negative solder pads of LED chips are arranged according to a third design;

FIG. 4 shows a top view of first LED chips and second LED chips substantially arranged in a circular pattern according to the present disclosure;

FIG. 5 shows a top view of first LED chips and second LED chips arranged in vertical lines and substantially arranged in a circular pattern according to the present disclosure;

FIG. 6 shows a cross-sectional view of a light-emitting structure according to the present disclosure using an air layer as a heat resistance structure;

FIG. 7 shows a cross-sectional view of a light-emitting structure according to the present disclosure using a layer of heat resistant material as a heat resistance structure; and

FIG. 8 to FIG. 14 are cross-sectional views of light-emitting structure according to the present disclosure respectively configured with different heat dissipation designs.

### DETAILED DESCRIPTION OF THE PREFERRED EMBODIMENTS

The following describes embodiments of “a light-emitting structure for providing a predetermined whiteness.” A person skilled in the art can understand other advantages and functions of the present disclosure. The present disclosure can also be realized by other embodiments. Details in this specification can be modified for different applications without deviating from the spirit of the present disclosure. Moreover, the figures of the present disclosure are illustrative and not true to actual dimensions. The following embodiments describe the present disclosure, but the present disclosure is not limited thereto.

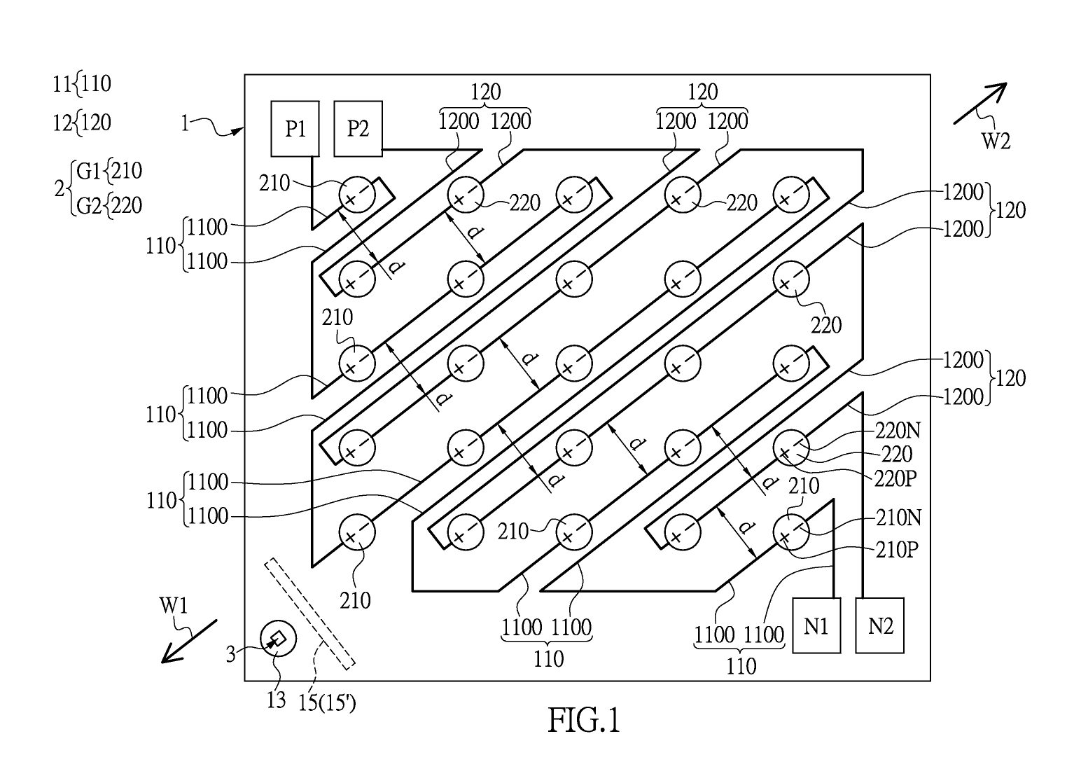

Referring to FIG. 1 to FIG. 3, a plurality of first light-emitting groups G1 and a plurality of second light-emitting groups G2 of a light-emitting unit 2 (object to be tested) of the present disclosure are alternately arranged. Each of the first light-emitting groups G1 includes one or more first LED chips 210. Each of the second light-emitting groups G2 includes one or more second LED chips 220. The quantity of the first LED chips 210 and the quantity of the second LED chips 220 may be the same or similar.

For example, the first LED chips 210 can be deep blue LED chips, producing light having a first predetermined wavelength substantially between 380 nm and 420 nm, specifically in the range of 400 nm to 420 nm. The second LED chips 220 can be normal blue LED chips, producing light having a second predetermined wavelength substantially between 445 nm and 465 nm. The color temperature produced by mixing white light from the first light-emitting groups G1 and white light from the second light-emitting groups G2 is substantially between 2500 K and 4500 K.

Specifically, when the surface areas (or light-emitting areas) of the first LED chips 210 and the second LED chips 220 are substantially the same, a desired whiteness can be obtained by controlling currents passing respectively through the first LED chips 210 and the second LED chips 220 (namely, “late stage current ratio adjustment”). The ratio of the currents is typically between 1:2 and 1:4. In the present embodiment, the ratio of the currents is 1:3. Of particular note, the ratio of the currents passing through the first LED chips 210 and the second LED chips 220 can be adjusted according to need, so the whiteness produced by mixing light from the first LED chips 210 and light from the second LED chips 220 can be adjusted according to need.

In another situation, when predetermined currents passing through the first LED chips 210 and the second LED chips 220 are substantially the same, a desired whiteness can be obtained by adjusting the ratio of the surface areas of the first LED chips 210 and the second LED chips 220 (namely, “early stage surface area ratio adjustment”). The ratio of the surface areas is typically between 0.8:2 and 0.8:4. In the present embodiment, the ratio of the surface areas is 0.8:3.

However, regarding methods of calculating CIE whiteness, the following formulas for calculating CIE whiteness can be defined for high and low color temperatures of 4000 K and 3000 K produced by the test object, according to the setting of a D 65 illuminating body (artificial daylight 6500 K) and CIE 1964 10 degrees standard:

W=[Y+800(x0−x)+1700(y0−y)]/K for 4000 K; and (1)

W=[Y+810(x0−x)+1700(y0−y)]/K for 3000 K. (2)

W is whiteness. Y is the Y-tristimulus value obtained by calculating light spectrum measured from a light emitting unit. (x0, y0) are specific coordinates of a reference light source on the CIE color coordinate (for example, when the color temperature is 4000 K, specific coordinates of a reference light source is (0.3138, 0.3310), when the color temperature is 3000 K, specific coordinates of a reference light source is (0.437, 0.4041). (x, y) are CIE coordinates measured from a light-emitting unit (for example, when the color temperature is 4000 K, a light-emitting unit of the present disclosure in the 380 nm to 780 nm spectrum has coordinates of (0.2981, 0.3253), when the color temperatures is 3000 K, another light-emitting unit of the present disclosure in the 380 nm to 780 nm spectrum has coordinates of (0.4348, 0.4081). K is a constant (for example, K can be a constant between 40 and 60). If K is 50 for example, with the abovementioned ratio of currents or ratio of surface areas of the present embodiment, a light-emitting unit having a predetermined whiteness W between 1 and 2.5 can be obtained.

Formulas for phosphor used in first light-emitting groups G1 and a plurality of second light-emitting groups G2 can be the same. For example, yellow-green phosphor can be combined with red phosphor. The yellow-green phosphor can be AB3O12 (e.g. Y3Al5O12:Ce, Y3(Al,Ga)5O12:Ce), Eu activated akali earth silicate, halophosphate, and β-SiAlON. The red phosphor preferably mixes two fluorescent bodies of different wavelengths and selected from the group consisting of Eu activated oxide, nitride, oxynitride, and (Sr, Ca)AlSiN3:Eu, and complex fluoride phosphor material activated with Mn⁴⁺. In order to avoid inability to increase whiteness, phosphor that are not affected by light emitted by the first LED chips 210 should be selected. Light emitted by the first LED chips 210 do not fall within its excitation spectrum, which is not between 380 nm and 420 nm. However, if the first and second LED chips 210, 220 are independent units, the phosphor of the second LED chips 220 do not have this requirement. Of course, the present disclosure can use different phosphor formulas in different applications.

Referring to FIG. 1 to FIG. 3, the present disclosure provides a light-emitting structure for providing a predetermined whiteness, comprising a substrate 1 and a light-emitting unit 2.

An upper surface of the substrate 1 has a meandering first conductive track 11 and a meandering second conductive track 12. The at least one first conductive track 11 has a plurality of first chip-mounting areas 110. The at least one second conductive track 12 has a plurality of second chip-mounting areas 120. The first chip-mounting areas 110 and the second chip-mounting areas 120 are alternately arranged. Additionally, each of the first chip-mounting areas 110 has at least two first chip-mounting lines 1100 arranged proximal to each other and in series. Each of the second chip-mounting areas 120 has at least two second chip-mounting lines 1200 arranged proximal to each other and in series. For example, as shown in FIG. 1, the meandering shapes of the first conductive track 11 and the second conductive track 12 are similar to an S-shaped serial connection. The meandering first conductive track 11 and the meandering second conductive track 12 are arranged close to each other in the form of interlocking fingers of two hands but without contacting each other, such that the first conductive track 11 and the second conductive track 12 present a line design of alternate arrangement. Additionally, the plurality of first chip-mounting lines 1100 and the plurality of second chip-mounting lines 1200 can be parallel to each other, but the present disclosure is not limited thereto.

Two opposite ends of the first conductive track 11 are respectively connected to a first positive bonding pad P1 and a first negative bonding pad N1, and two opposite ends of the second conductive track 12 are respectively connected to a second positive bonding pad P2 and a second negative bonding pad N2. For example, the first positive bonding pad P1 and the second positive bonding pad P2 can be arranged proximal to each other at a corner of the substrate 1, and the first negative bonding pad N1 and the second negative bonding pad N2 are arranged proximal to each other at the opposite corner on the substrate 1. The width of the first conductive track 11 extending from the first positive bonding pad P1 to the first negative bonding pad N1, and the width of the second conductive track 12 extending from the second positive bonding bad P2 to the second negative bonding pad N2 gradually increase and decrease along a diagonal line on the substrate 1, thereby increasing the area of distribution of the first conductive track 11 and the second conductive track 12.

Moreover, the light-emitting unit 2 includes a plurality of first light-emitting groups G1 and a plurality of second light-emitting groups G2. Each of the first light-emitting groups G1 includes one or more first LED chips 210. Each of the second light-emitting groups G2 includes one or more second LED chips 220. The quantity of the first LED chips 210 and the quantity of the second LED chips 220 can be the same or similar. The light produced by each of the first LED chips 210 has a first predetermined wavelength. The light produced by each of the second LED chips 220 has a second predetermined wavelength. The second predetermined wavelength is greater than the first predetermined wavelength.

Specifically, as shown in FIG. 1, each of the positive bonding pads 210P of the first LED chips 210 and each of the positive bonding pads 220P of the second LED chips 220 are all directed toward a first predetermined direction W1 relative to the substrate 1. Each of the negative bonding pads 210N of the first LED chips 210 and each of the negative bonding pads 220N of the second LED chips 220 are all directed toward a second predetermined direction W2 relative to the substrate 1. The first predetermined direction W1 and the second predetermined direction W2 are opposite directions. By this configuration, regarding each individual chip, the aspect (orientation relative to the substrate 1) of the positive and negative bonding pads (210P, 210N) of each of the first LED chips 210 is the same as the aspect (orientation relative to the substrate 1) of the positive and negative bonding pads (220P, 220N) of each of the second LED chips 220. During the process of disposing chips, the positive terminals and the negative terminals of the first LED chips 210 and the second LED chips 220 do not need to be turned, increasing production efficiency.

Specifically, in order to achieve the design of the above-mentioned “the orientation relative to the substrate 1 of the positive and negative bonding pads (210P, 210N) of each of the first LED chips 210 is the same as the orientation relative to the substrate 1 of the positive and negative bonding pads (220P, 220N) of each of the second LED chips 220,” the one or more first LED chips 210 of each of the first light-emitting groups G1 can only be placed on one of the first chip-mounting lines 1100 of the respective first chip-mounting area 110, and the one or more second LED chips 220 of each of the second light-emitting groups G2 can only be placed on one of the second chip-mounting lines 1200 of the respective second chip-mounting area 120. For example, as shown in FIG. 1, in order to orient the positive bonding pad 210P of each of the first LED chips 210 toward the first predetermined direction W1, the one or more first LED chips 210 of each of the first light-emitting groups G1 is placed on the first chip-mounting line 1100 closer to the first positive bonding pad P1 of two neighboring first chip-mounting lines 1100, preferably. Likewise, in order to orient the positive bonding pad 220P of each of the second LED chips 220 toward the first predetermined direction W1, the one or more second LED chips 220 of each of the second light-emitting groups G2 is placed on the second chip-mounting line 1200 further from the second positive bonding pad P2 of two neighboring second chip-mounting lines 1200, preferably.

In order to achieve the design of “the positive terminals and the negative terminals of the first LED chips 210 and the second LED chips 220 do not need to be turned,” the one or more first LED chips 210 of each of the first light-emitting groups G1 can be disposed on the same corresponding first chip-mounting line 1100 of the first chip-mounting area 110, to form first LED chips 210 which do not need to be turned to realign the positive terminal and the negative terminal during chip disposing process, and the one or more second LED chips 220 of each of the second light-emitting groups G2 can be disposed on the same corresponding second chip-mounting line 1200 of the second chip-mounting area 120, to form second LED chips 220 which do not need to be turned to realign the positive terminal and the negative terminal during chip disposing process. Additionally, since the first chip-mounting areas 110 and the second chip-mounting areas 120 are alternately arranged, the first light-emitting groups G1 and the second light-emitting groups G2 are also alternately arranged, thereby increasing the light mixing effect of light-emitting groups of chips having different wavelengths.

For example, the first LED chips 210 and the second LED chips 220 can be alternately arranged as an array, so that the first LED chips 210 and the second LED chips 220 present an alternating arrangement from a vertical or a horizontal perspective. Additionally, the first chip-mounting lines 1100 having first LED chips 210 disposed thereon and the second chip-mounting lines 1200 having second LED chips 220 disposed thereon can be parallel to each other and have the same interval distance D therebetween, such that any neighboring first light-emitting group G1 and second light-emitting group G2 can be parallel to each other and be separate by an interval distance D. Therefore, the light produced by the plurality of first light-emitting groups G1 and the plurality of second light-emitting groups G2 of the light-emitting unit 2 can be preferably mixed.

Specifically, the first conductive track 11 and the second conductive track 12 extend along a diagonal line of the substrate 1 such that the horizontal width of the meandering tracks present changes of “gradual increase and decrease,” so that the quantities of the first LED chips 210 of the first light-emitting groups G1 and the quantities of the second LED chips 220 of the second light-emitting groups G2 sequentially decrease from the middle of the light-emitting unit 2 toward two opposite sides of the light-emitting unit 2, or sequentially increase from two opposite sides of the light-emitting unit 2 toward the middle of the light-emitting unit 2.

For example, the quantities of the first LED chips 210 and the quantities of the second LED chips 220 sequentially increase from two opposite corners toward the middle according to the respective formulas 2n−1 and 2n, wherein n is the sequence number of the first light-emitting groups G1 and the second light-emitting groups G2 starting from 1. Therefore, the quantities of the first LED chips 210 increase from the two corners to the middle of the light-emitting unit 2 according to the sequence (2×1−1=1, 2×2−1=3, 2×3−1=5), and the quantities of the second LED chips 220 increase from the two corners to the middle of the light-emitting unit 2 according to the sequence (2×1=2, 2×2=4). By this configuration, the quantities of first LED chips 210 of two neighboring first light-emitting groups G1 differs by two, the quantities of second LED chips 220 of two neighboring second light-emitting groups G2 differs by two, and the quantities of LED chips (210, 220) of a first light-emitting group G1 and a neighboring second light-emitting group G2 differ by 1. Of course, the present disclosure is not limited to the above example.

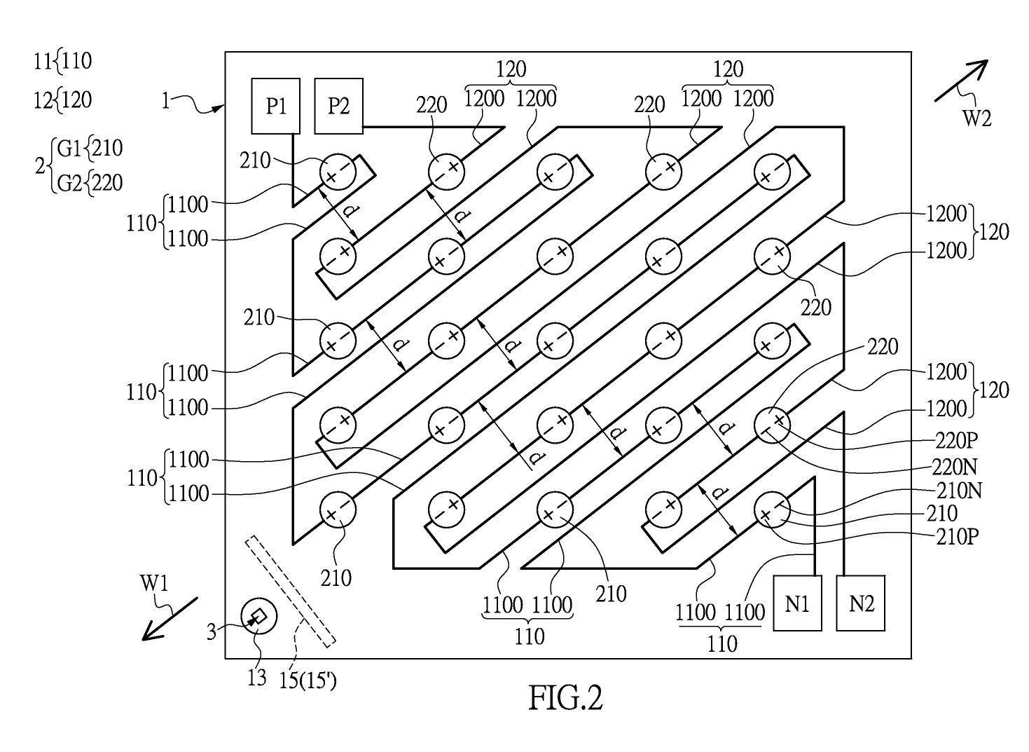

Of particular note, as shown in FIG. 2, each of the positive bonding pads 210P of the first LED chips 210 and each of the positive bonding pads 220P of the second LED chips 220 are respectively oriented toward the first predetermined direction W1 and the second predetermined direction W2 with respect to the substrate 1, and each of the negative bonding pads 210N of the first LED chips 210 and each of the negative bonding pads 220N of the second LED chips 220 are respectively oriented toward the second predetermined direction W2 and the first predetermined direction W1 with respect to the substrate 1, such that the positive and negative bonding pads (210P, 210N) of the first LED chips 210 have aspects opposite to those of the positive and negative bonding pads (220P, 220N) of the second LED chips 220. In other words, regarding single chips, according to needs, the aspect of the positive and negative bonding pads (210N, 210P) of each of the first LED chips 210 can be same as (as shown in FIG. 1) or opposite to (as shown in FIG. 2) the aspect of the positive and negative bonding pads (220N, 220P) of each of the second LED chips 220.

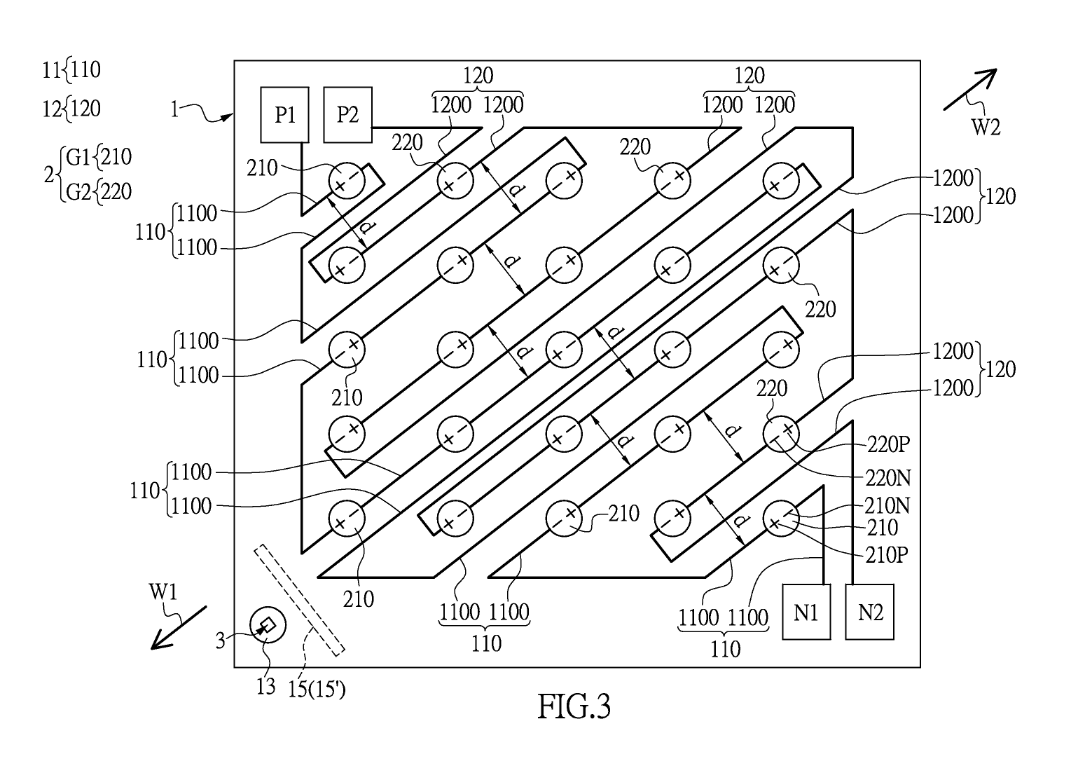

Additionally, as shown in FIG. 3, the positive bonding pad 210P and the negative bonding pad 210N of the first LED chip 210 of any of the first light-emitting groups G1 are arranged respectively toward the first predetermined direction W1 and the second predetermined direction W2, and the positive bonding pad 210P and the negative bonding pad 210N of the first LED chip 210 of another first light-emitting group G1 are arranged oppositely, such that the positive bonding pad 210P and the negative bonding pad 210N of the one or more first LED chips 210 are arranged toward the first predetermined direction W1 and the second predetermined direction W2. Moreover, each of the second light-emitting groups G2 and another neighboring second light-emitting group G2 are also “arranged with alternating aspects of positive and negative bonding pads (as shown in FIG. 3).” In other words, according to need, the present disclosure can use “the same aspects of positive and negative bonding pads (as shown in FIG. 1),” “opposite aspects of positive and negative bonding pads (as shown in FIG. 2),” or “alternating aspects of positive and negative bonding pads (as shown in FIG. 3).” However, the present disclosure is not limited to the above.

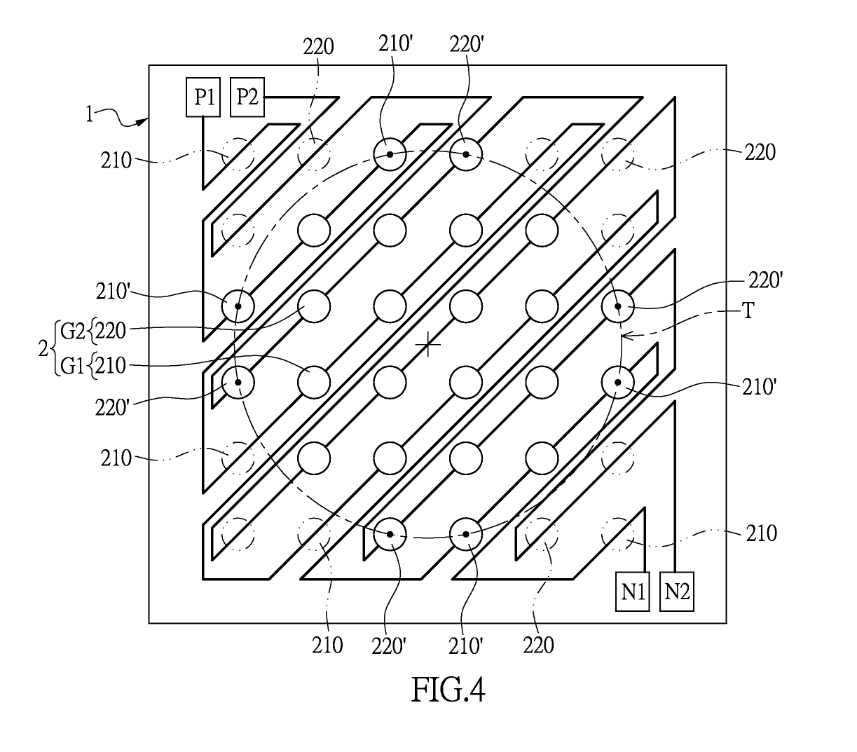

Referring to FIG. 4, taking the 6×6 array of LED chips (210, 220) for example, the total quantity of second Led chips 210 is equal to the total quantity of the second LED chips 220. When the LED chips proximal to the four corners of the substrate 1 are removed (as shown by dotted lines labeled as 210, 220 in FIG. 4), the first LED chips 210 and the second LED chips 220 present an arrangement distribution which is “approximately circular.” Specifically, 4 of the first LED chips 210 are positioned at the outer periphery (labeled as 210′), and 4 of the second LED chips 220 are positioned at the outer periphery (labeled as 220′). Whether using the 4 first LED chips 210′ at the outer periphery or the 4 second LED chips 220′ at the outer periphery as basis (shown as black dots in FIG. 4), a circular path T can be drawn as shown in FIG. 4. In a preferred design, the circular track T drawn by using the 4 first LED chips 210′ at the outer periphery as basis and the circular track T drawn by using the 4 second LED chips 220′ at the outer periphery as basis substantially overlap or completely overlap to form a single circular track T.

Additionally, regardless of whether the first chip-mounting lines 1100 and the second chip-mounting lines 1200 are “slantedly designed” or “vertically designed,” the first chip-mounting lines 1100 and the second chip-mounting lines 1200 are preferably parallel. The first LED chips 210 and the second LED chips 220 do not need to be turned during the chip mounting process. Namely, the positive bonding pad 210P of each of the first LED chips 210 and the positive bonding pad 220P of each of the second LED chips 220 face toward the first predetermined direction W1′, and the negative bonding pad 210N of each of the first LED chips 210 and the negative bonding pad 220N of each of the second LED chips 220 face toward the second predetermined direction W2′.

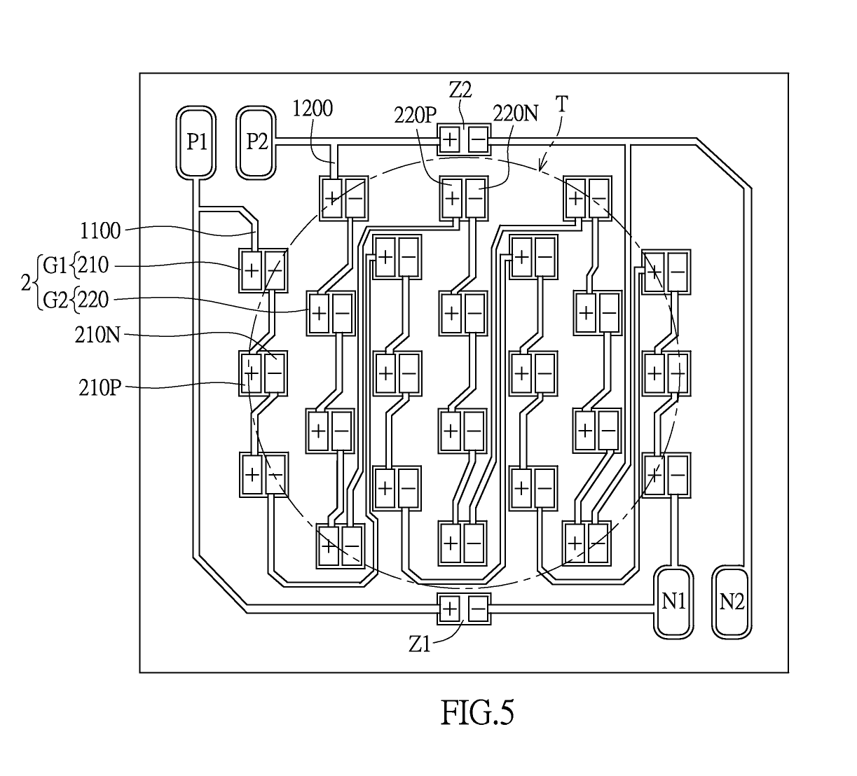

As shown in FIG. 5, the first chip-mounting lines 1100 and the second chip-mounting lines 1200 can be modified from the “slanted design” of FIG. 4 to a “vertical design.” This vertical design also allows the first LED chips 210 and the second LED chips 220 to present an arrangement distribution which is “substantially circular.” In other words, when presenting a “circular” arrangement distribution, the total quantity of the first LED chips 210 and the total quantity of the second LED chips 220 are equal. The quantities of LED chips (210, 220) of a first light-emitting group G1 and a neighboring second light-emitting group G2 differ by 1. Therefore when the quantity of the first LED chips 210 of each of the first light-emitting groups G1 is N, the quantity of the second LED chips 220 of each of the second light-emitting groups G2 is N+1, the quantity of the first light-emitting groups G1 is N+1, and the quantity of the second light-emitting groups G2 is N, so the total quantity of each type of LED chip is N(N+1).

Of particular note, a by pass route can be arranged between and connecting the first positive bonding pad P1 and the first negative bonding pad N1. A protective circuit can be disposed on the by pass route to prevent static breakdown, such as a first zener diode Z1. Likewise, a by pass route can be arranged between and connecting the second positive bonding pad P2 and the second negative bonding pad N2. A protective circuit can be disposed on the by pass route to prevent static breakdown, such as a second zener diode Z2.

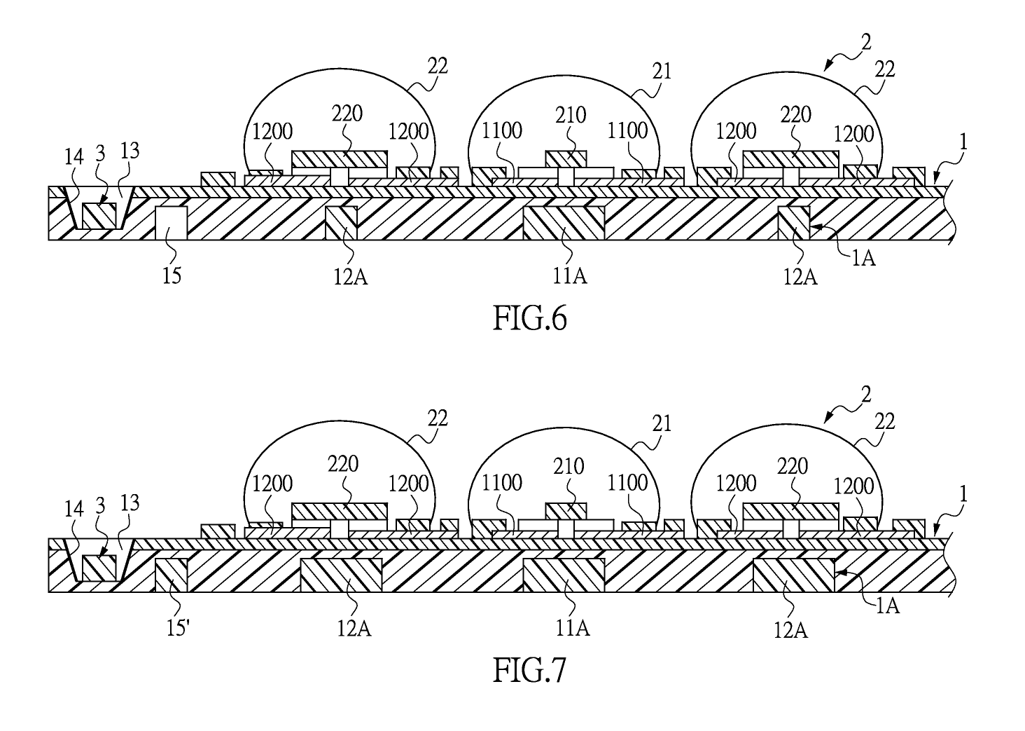

Additionally, as shown in FIG. 1, FIG. 6 and FIG. 7, the upper surface of the substrate 1 has an accommodating groove 13 for accommodating an electronic component 3. The inner surface of the accommodating groove 13 has a light-absorbing coating 14, and the interior of the substrate 1 has a thermal resistant structure disposed between the electronic component 3 and the light-emitting unit 2. For example, the substrate 1 can be a ceramic plate with a high reflection rate. The ceramic plate can have reflection rates of 102% and 100.9% respectively for the first LED chips 210 of 410 nm and the second LED chips 220 of 450 nm, thereby increasing the lighting effect and the whiteness of the present disclosure. Moreover, the electronic component 3 can be an optical sensor, and the light-absorbing coating 14 can be a black coating for reducing reflection, increasing the sensing effect of the optical sensor. Additionally, the thermal resistant structure can be an air layer 15 (as shown in FIG. 2) or a high thermal resistance material 15′ whose thermal resistance is higher than that of the substrate 1 (as shown in FIG. 3), limiting the heat produced by the light-emitting unit 2 from being transmitted to the electronic component 3. Additionally, regarding the positioning of the electronic component 3 and the thermal resistant structure, for example as shown in FIG. 1, when the electronic component 3 is disposed proximal to a corner of the substrate 1, the thermal resistant structure (15, 15′) can be slantedly disposed between the light-emitting unit 2 and the electronic component 3. According to another possible positioning, when the electronic component 3 is disposed proximal to a transverse (horizontal) edge of the substrate 1, the thermal resistant structure can be vertically (or levelly) disposed between the light-emitting unit 2 and the electronic component 3. Specifically, the thermal resistant structure on the substrate 1 and the subsequent thermal conducting unit can be formed at the same time. In other words, a plurality of indentations or through holes is formed on the back of the substrate 1 at predetermined positions corresponding to the positions of the thermal resistant structure and the thermal conducting unit. The depths of indentations are the same. Then, the indentations or through holes of the thermal resistant structure can be unfilled (and air) or filled with material having high thermal resistance. The indentations or through holes of the thermal conducting unit can be filled with similar or different materials having high thermal conductivity. In other words, the thermal conductivities k1, k2 and k3 of respectively the substrate, the thermal resistant structure and the thermal conducting unit satisfy the relationship of k3>k1>k2. The present embodiment takes the strength of the substrate into consideration and employs a design of indentations.

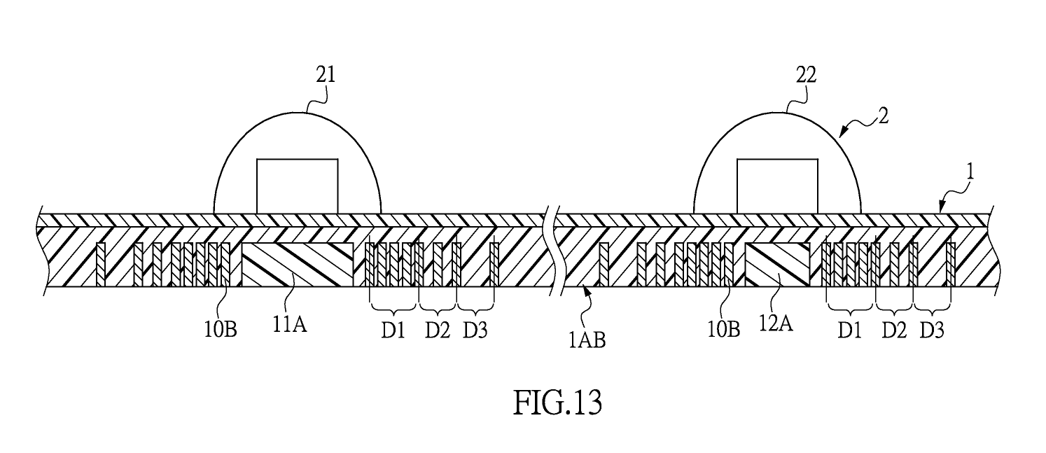

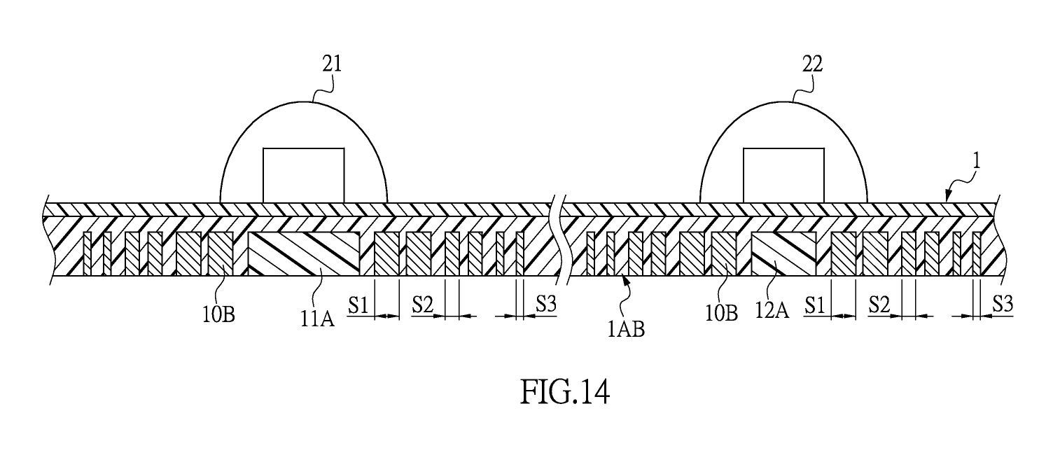

Specifically, referring to FIG. 6 to FIG. 14, the substrate 1 can be configured with different heat dissipating designs, such as a thermal conducting unit 1A, a thermal spreading unit 1B, etc.

Referring to FIG. 6 and FIG. 7, the substrate 1 further includes a thermal conducting unit 1A embedded in the substrate 1, and the thermal conducting unit 1A includes a plurality of first heat dissipating structures 11A disposed under the plurality of first LED chips 210 and a plurality of second heat dissipating structures 12A disposed under the plurality of second LED chips 220. For example, the first LED chips 210 and the second LED chips 220 become a first LED unit 21 and a second LED unit 22 after packaging (for example using similar or different fluorescent gel for packaging). When the wavelength produced by the first LED chips 210 of the first LED unit 21 is smaller than the wavelength produced by the second LED chips 220 of the second LED unit 22, the first heat dissipating structures 11A and the second heat dissipating structures 12A can use the following design, for balancing the heat dissipation of the first LED unit 21 and the second LED unit 22. Firstly, in the first type, when the first heat dissipating structures 11A and the second heat dissipating structures 12A use materials having similar heat dissipating ability, the overall dimensions (or volume) of the first heat dissipating structures 11A is greater than the overall dimensions (or volume) of the second heat dissipating structures 12A. Additionally, in the second type, when the dimensions of the first heat dissipating structures 11A and the second heat dissipating structures 12A are similar, the heat dissipating ability of the material used by the first heat dissipating structures 11A is greater than the heat dissipating ability of the material used by the second heat dissipating structures 12A. However, the present disclosure is not limited thereto. Additionally, the first LED unit 21 and the second LED unit 22 of different wavelengths results in different contact face temperatures. Therefore, the heat transfer rate Q1 of the first heat dissipating structures 11A and the heat transfer rate Q2 of the second heat dissipating structures 12A can have a ratio Q1:Q2=1:0.86−0.95.

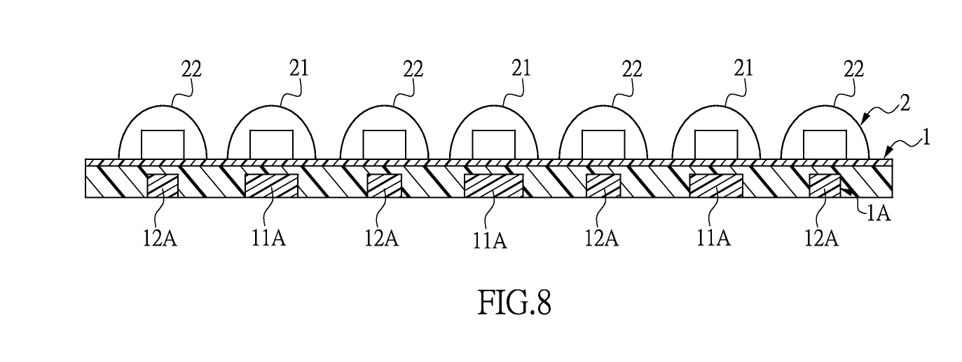

Referring to FIG. 8, the dimensions of the first heat dissipating structures 11A and the second heat dissipating structures 12A gradually decrease from the center of the substrate 1 toward the periphery of the same. By this configuration, the difference between the contact face temperatures of the “first and second LED units (21, 22) at the central region of the substrate 1” and the “first and second LED units (21, 22) at the peripheral region (the region surrounding the central region) of the substrate 1” is reduced. Specifically, looking from the center of the substrate 1 toward the periphery, the dimensions of the first heat dissipating structures 11A sequentially decrease by 10% from the center to the periphery (namely the dimensions of two neighboring first heat dissipating structures 11A differ by 10%), and the dimensions of the second heat dissipating structures 12A sequentially decrease by 10% from the center to the periphery (namely the dimensions of two neighboring second heat dissipating structures 12A differ by 10%). Additionally, the heat dissipating ability of a second heat dissipating structure 12A is roughly 0.86-0.95 times that of a neighboring first heat dissipating structure 11A.

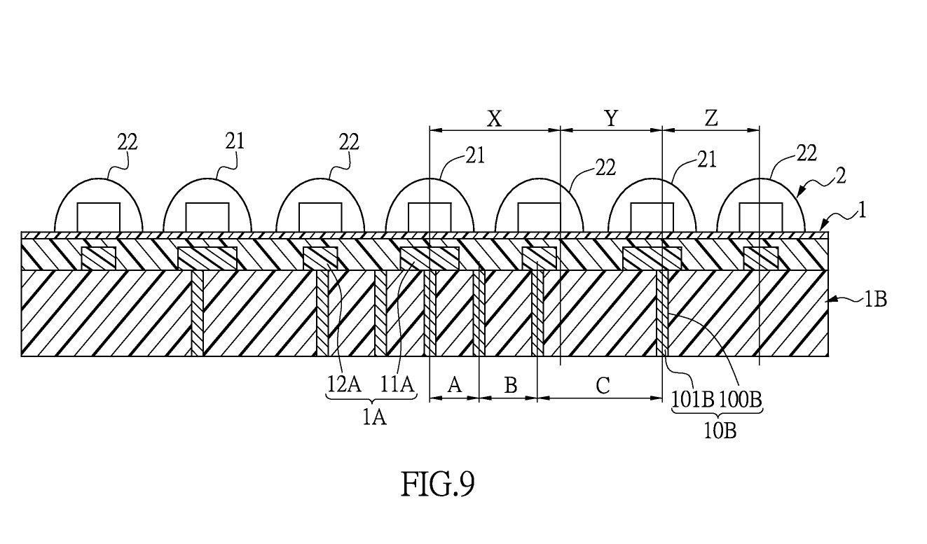

Referring to FIG. 9 to FIG. 11, the bottom of the substrate 1 further includes a thermal spreading unit 1B contacting the thermal conducting unit 1A, wherein the interior of the thermal spreading unit 1B includes a plurality of heat dissipating channels 10B which are separate. By adjusting the shape and arrangement of the heat dissipating channels 10B, the difference between the contact face temperatures of the “first and second LED units (21, 22) at the central region of the substrate 1” and the “first and second LED units (21, 22) at the peripheral region (the region surrounding the central region) of the substrate 1” is reduced.

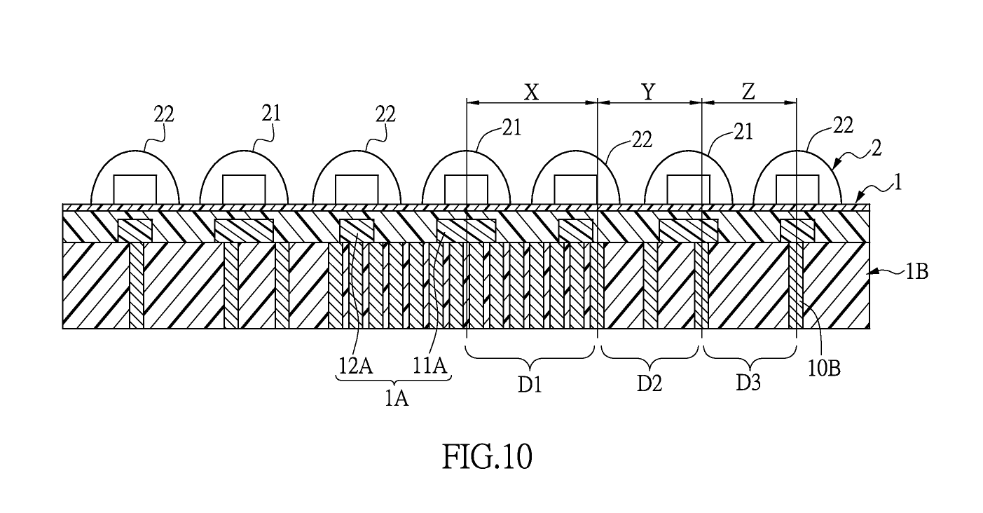

When the dimensions of the heat dissipating channels 10B are similar, the gap distances (A, B, C) between two neighboring heat dissipating channels 10B increase from the center of the thermal spreading unit 1B toward the periphery of the same, or the volumetric density (D1, D2, D3) of the heat dissipating channels 10B occupying the thermal spreading unit 1B decreases from the center to the periphery of the thermal spreading unit 1B. By this configuration, the heat dissipating channels 10B are sequentially arranged in the direction of “from the center to the periphery of the thermal spreading unit 1B” or “from the periphery to the center of the thermal spreading unit 1B,” to form an incremental thermal conduction structure. Typically, temperature closer to the center is higher. Marking boundaries at every difference of five degrees Kelvin, three heat dissipating regions are defined as shown in FIG. 9 and FIG. 10 presenting a side cross-sectional view of the light-emitting structure. The three heat dissipating regions (X, Y, Z) progressively cover less horizontal distance from the heat dissipating region X to the heat dissipating region Z. For example, the ratio of the distances of the three heat dissipating regions can be X:Y:Z=5:4:3. When the dimensions of the heat dissipating channels 10B are similar, the gap distances (A, B, C) between two neighboring heat dissipating channels 10B increases from the center to the periphery of the thermal spreading unit 1B (e.g. A:B:C=3:4:5), or the volumetric densities (D1, D2, D3) of heat dissipating channels 10B occupying the thermal spreading unit 1B decreases from the heat dissipating region X to the heat dissipating region Z (e.g. D1:D2:D3=6.5:2:1).

Additionally, each of the heat dissipating channels 10B can be a solid heat conducting column formed by a through hole 100B and a heat conducting material 101B (e.g. metal material having high thermal conductivity) completely filling the through hole 100B. The heat dissipating channels 10B can completely pass through the thermal spreading unit 1B. However the present disclosure is not limited thereto. For example, the heat conducting material 101B does not need to completely fill the corresponding through holes 100B, and the heat dissipating channels 10B do not need to completely pass through the thermal spreading unit 1B.

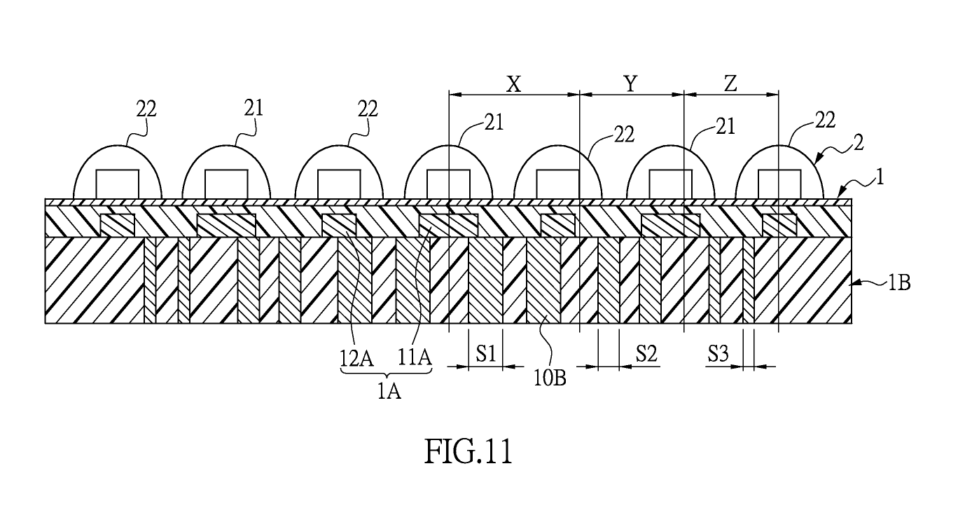

Referring to FIG. 11, the interior of the thermal spreading unit 1B includes a plurality of separate heat dissipating channels 10B, and the dimensions (S1, S2, S3) of the thermal dissipating channels 10B decrease from the center to the periphery of the thermal spreading unit 1B.

For example, marking boundaries at every difference of five degrees Kelvin, three heat dissipating regions are defined as shown in FIG. 11 presenting a side cross-sectional view of the light-emitting structure. The three heat dissipating regions (X, Y, Z) progressively cover less horizontal distance from the heat dissipating region X to the heat dissipating region Z. For example, the ratio of the distances of the three heat dissipating regions can be X:Y:Z=5:4:3. The heat dissipating channels 10B have different dimensions, and the dimensions (S1, S2, S3) of the heat dissipating channels 10B decrease from the heat dissipating region X to the heat dissipating region Y (e.g. S1:S2:S3=5:4:3). Therefore, the heat dissipating effect of the “first and second LED units (21, 22) at the central region of the thermal spreading unit 1B” is better than the heat dissipating effect of the “first and second LED units (21, 22) at the peripheral region of the thermal spreading unit 1B.”

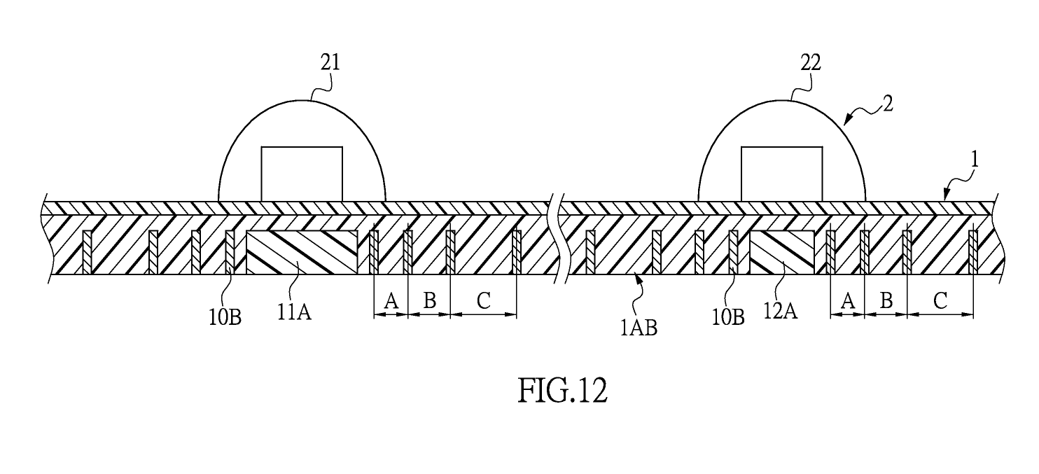

Referring to FIG. 12 to FIG. 14, the thermal conducting unit 1A and the thermal spreading unit 1B are integrated to form a compound thermal dissipating layer 1AB. Specifically, each of the first heat dissipating structures 11A positioned in the compound heat dissipating layer 1AB is closely surrounded by heat dissipating channels 10B which are separate. When the heat dissipating channels 10B have similar dimensions, the gap distances (A, B, C) between two neighboring heat dissipating channels 10B increase in the direction from the center to the periphery of the corresponding first heat dissipating structure 11A, or the volumetric densities (D1, D2, D3) of the heat dissipating channels 10B decrease in the direction from the center to the periphery of the corresponding first heat dissipating structure 11A. Likewise, each of the second heat dissipating structures 12A positioned in the compound heat dissipating layer 1AB is closely surrounded by heat dissipating channels 10B which are separate and have similar dimensions, and the gap distances (A, B, C) between two neighboring heat dissipating channels 10B increase in the direction from the center to the periphery of the corresponding second heat dissipating structure 12A, or the volumetric densities (D1, D2, D3) of the heat dissipating channels 10B decrease in the direction from the center to the periphery of the corresponding second heat dissipating structure 12A. When the dimensions of the heat dissipating channels 10B are different, the dimensions (S1, S2, S3) of the heat dissipating channels 10B decrease in the direction from the center to the periphery of the corresponding first heat dissipating structure 11A. Likewise, each of the second heat dissipating structures 12A positioned in the compound heat dissipating layer 1AB is closely surrounded by heat dissipating channels 10B which are separate, and the dimensions (S1, S2, S3) of the heat dissipating channels 10B decrease in the direction from the center to the periphery of the corresponding second heat dissipating structure 12A. By this method, the temperature difference between the first and second LED units (21, 22) of different wavelengths can be reduced.

In summary of the above, the present disclosure has the following advantages. The light mixing effect is increased between the plurality of first light-emitting groups G1 and the plurality of second light-emitting groups G2 of different wavelengths through the design of “the first chip-mounting areas 110 and the second chip-mounting areas 120 are alternately arranged, such that the first light-emitting groups G1 and the second light-emitting groups G2 are alternately arranged.” Additionally, by “early stage surface area ratio adjustment” or “late stage current ratio adjustment,” the present disclosure can provide different whiteness according to need.

The descriptions illustrated supra set forth simply the preferred embodiments of the present disclosure; however, the characteristics of the present disclosure are by no means restricted thereto. All changes, alternations, or modifications conveniently considered by those skilled in the art are deemed to be encompassed within the scope of the present disclosure delineated by the following claims.

What is claimed is:

1. A light-emitting structure comprising:
a substrate having at least one meandering first conductive track and at least one meandering second conductive track, wherein each of the first conductive tracks has a plurality of first chip-mounting areas, and each of the second conductive tracks has a plurality of second chip-mounting areas; and
a light-emitting unit including a plurality of first light-emitting groups respectively disposed on the first chip-mounting areas and a plurality of second light-emitting groups respectively disposed on the second chip-mounting areas, wherein each of the first light-emitting groups includes one or a plurality of first LED chips, and each of the second light-emitting groups includes one or a plurality of second LED chips;
wherein the first chip-mounting areas and the second chip-mounting areas are alternately arranged, and the first light-emitting groups and the second light-emitting groups are alternately arranged;
wherein the first LED chip produces light having a first predetermined wavelength, the second LED chip produces light having a second predetermined wavelength, and the second predetermined wavelength is greater than the first predetermined wavelength;
wherein when the first LED chip and the second LED chip have substantially same surface areas, the ratio of a current passing through the first LED chip to a current passing through the second LED chip is 1:2 to 1:4;
wherein when currents passing through the first LED chip and the second LED chip is substantially the same, the ratio of a surface area of the first LED chips to a surface area of the second LED chip is 0.8:2 to 0.8:4.

2. The light-emitting structure according to claim 1, wherein the quantity of the first LED chips is close to the quantity of the second LED chips, the first predetermined wavelength is between 380 nm and 420 nm, the second predetermined wavelength is between 445 nm and 465 nm, and a mixture of white light produced by the first light-emitting groups and white light produced by the second light-emitting groups has a color temperature between 2500 K and 4500 K.

3. The light-emitting structure according to claim 1, wherein each of the first chip-mounting areas has at least two first chip-mounting lines, each of the second chip-mounting areas has at least two second chip-mounting lines, the one or a plurality of first LED chips of each of the first light-emitting groups is disposed on one of the first chip-mounting lines of the corresponding first chip-mounting area, and the one or a plurality of second LED chips of each of the second light-emitting groups is disposed on one of the second chip-mounting lines of the corresponding second chip-mounting area.

4. The light-emitting structure according to claim 3, wherein the first chip-mounting lines with the first LED chips disposed thereon and the second chip-mounting lines with the second LED chips disposed thereon are parallel, any neighboring first light-emitting group and second light-emitting group are parallel and have the same gap distance therebetween, and the first LED chips and the second LED chips are alternately arranged to form an array.

5. The light-emitting structure according to claim 1, wherein the substrate further includes a plurality of first heat dissipating structures disposed under the plurality of the first LED chips and a plurality of second heat dissipating structures disposed under the plurality of second LED chips.

6. The light-emitting structure according to claim 5, wherein when the first heat dissipating structures and the second heat dissipating structures use material of the same heat dissipating abilities, the dimensions of the first heat dissipating structures are greater than the dimensions of the second heat dissipating structures, and when the dimensions of the first heat dissipating structures and the dimensions of the second heat dissipating structures are substantially the same, the heat dissipating ability of the material used by the first heat dissipating structures is greater than the heat dissipating ability of the material used by the second heat dissipating structures.

7. The light-emitting structure according to claim 5, wherein the dimensions of the first heat dissipating structures and the dimensions of the second heat dissipating structures decrease in the direction from the center to the periphery of the substrate.

8. The light-emitting structure according to claim 7, wherein the ratio of the decreasing dimensions of the first heat dissipating structures in the direction from the center to the periphery of the substrate is substantially the same as the ratio of the decreasing dimensions of the second heat dissipating structures in the direction from the center to the periphery of the substrate.

9. The light-emitting structure according to claim 5, wherein the substrate further includes a thermal conducting unit having a plurality of first and second heat dissipating structures and a thermal spreading unit positioned under the thermal conducting unit.

10. The light-emitting structure according to claim 9, wherein the interior portion of the thermal spreading unit includes a plurality of separate heat dissipating channels, and the plurality of separate heat dissipating channels is selected from one of a first definition, a second definition, and a third definition;
wherein the first definition is defined as follows: the dimensions of the heat dissipating channels are the same, and the gap distance between two neighboring heat dissipating channels decrease from the center to the periphery of the thermal conducting unit;
wherein the second definition is defined as follows: the dimensions of the heat dissipating channels are the same, and the volumetric densities of the heat dissipating channels occupying the thermal spreading unit decrease from the center to the periphery of the thermal conducting unit;
wherein the second definition is defined as follows: the dimensions of the heat dissipating channels decrease from the center to the periphery of the thermal conducting unit.

11. The light-emitting structure according to claim 5, wherein each of the first heat dissipating structures and the second heat dissipating structures are surrounded by a plurality of separate heat dissipating channels, and the plurality of heat dissipating channels is selected from one of a first definition, a second definition, and a third definition;
wherein the first definition is defined as follows: the dimensions of the heat dissipating channels are the same, and the gap distance between two neighboring heat dissipating channels decrease from the center to the periphery of the thermal conducting unit;
wherein the first definition is defined as follows: the dimensions of the heat dissipating channels are the same, and the volumetric densities of the heat dissipating channels occupying the thermal spreading unit decrease from the center to the periphery of the thermal conducting unit;
wherein the first definition is defined as follows: the dimensions of the heat dissipating channels decrease from the center to the periphery of the thermal conducting unit.

12. The light-emitting structure according to claim 1, wherein the upper surface of the substrate has an accommodating groove for accommodating an electronic component, the inner portion of the substrate further includes a plurality of thermal conducting units positioned under the first and second LED chips and a thermal resistant structure disposed between the electronic component and the light-emitting unit, wherein the thermal conductivities of the substrate, the thermal resistant structure and the thermal conducting unit are respectively k1, k2 and k3, and k3>k1>k2.

13. The light-emitting structure according to claim 1, wherein the plurality of the first light-emitting groups and the plurality of the second light-emitting groups use the same phosphor formula.

14. The light-emitting structure according to claim 13, wherein the phosphor formula uses a yellow-green phosphor to combine with a red phosphor, the yellow-green phosphor is selected from one of Y3Al5O12:Ce, Y3(Al,Ga)5O12:Ce, Eu activated akali earth silicate, halophosphate, and β-SiAlON, and the red phosphor preferably mixes two fluorescent bodies of different wavelengths and selected from the group consisting of Eu activated oxide, nitride, oxynitride, (Sr, Ca)AlSiN3:Eu, and complex fluoride phosphor material activated with Mn4+.

15. A light-emitting structure, comprising:
a substrate; and
a light-emitting unit including a plurality of first light-emitting groups disposed on the substrate and a plurality of second light-emitting groups disposed on the substrate, wherein each of the first light-emitting groups includes one or a plurality of first LED chips, and each of the second light-emitting groups includes one or a plurality of second LED chips;
wherein the first chip-mounting areas and the second chip-mounting areas are alternately arranged, and the first light-emitting groups and the second light-emitting groups are alternately arranged;
wherein the first LED chip produces light having a first predetermined wavelength, the second LED chip produces light having a second predetermined wavelength, and the second predetermined wavelength is greater than the first predetermined wavelength;
wherein light obtained by mixing white light produced by the first light-emitting groups and white light produced by the second light-emitting groups has a whiteness between 1 and 2.5, for high and low color temperatures the formulas for calculating CIE whiteness are as follows:
W=[Y+800(x0−x)+1700(y0−y)]/K for 4000K, and
W=[Y+810(x0−x)+1700(y0−y)]/K for 3000K;
wherein W is CIE whiteness, Y is the Y-tristimulus value obtained by calculating light spectrum measured from the light emitting unit, (x0, y0) are specific coordinates of a reference light source on the CIE color coordinate, (x, y) are CIE coordinates measured from the light-emitting unit, and K is a constant.

16. The light-emitting structure according to claim 15, wherein the substrate further includes at least one of a plurality of heat dissipating structures and a plurality of thermal spreading units disposed under the plurality of the first and second LED chips.

17. A light-emitting structure comprising:
a substrate having at least one meandering first conductive track and at least one meandering second conductive track;
a plurality of first LED chips disposed on the first conductive track and having a wavelength between 380 nm and 420 nm; and
a plurality of second LED chips disposed on the second conductive track and having a wavelength greater than that of the first LED chips;
wherein the first conductive track and the second conductive track are alternately arranged;
wherein when the first LED chip and the second LED chip have substantially same surface areas, a current passing through the first LED chip is smaller than a current passing through the second LED chip;
wherein when currents passing through the first LED chip and the second LED chip is substantially the same, a surface area of the first LED chips is smaller than a surface area of the second LED chip.

18. The light-emitting structure according to claim 17, wherein the quantity of the first LED chips is close to the quantity of the second LED chips, and a mixture of white light produced by the first light-emitting groups and white light produced by the second light-emitting groups has a color temperature between 2500 K and 4500 K and a whiteness between 1 and 2.5.

19. The light-emitting structure according to claim 17, wherein the substrate further includes a plurality of first heat dissipating structures disposed under the plurality of the first LED chips and a plurality of second heat dissipating structures disposed under the plurality of second LED chips, wherein when the first heat dissipating structures and the second heat dissipating structures use material of the same heat dissipating abilities, the dimensions of the first heat dissipating structures are greater than the dimensions of the second heat dissipating structures, wherein when the dimensions of the first heat dissipating structures and the dimensions of the second heat dissipating structures are substantially the same, the heat dissipating ability of the material used by the first heat dissipating structures is greater than the heat dissipating ability of the material used by the second heat dissipating structures.

20. The light-emitting structure according to claim 17, wherein the substrate further includes at least one of a plurality of heat dissipating structures and a plurality of thermal spreading units disposed under the plurality of the first and second LED chips.
